(19) United States
(12) Patent Application Publication
(10) Pub. No.: US 2026/0371732 A1
(43) Pub. Date: Nov. 19, 2026

(54) ARRAY SUBSTRATE AND DISPLAY DEVICE

(71) Applicants: WUHAN BOE OPTOELECTRONICS TECHNOLOGY CO., LTD., Wuhan, Hubei (CN); BOE TECHNOLOGY GROUP CO., LTD., Beijing (CN)

(72) Inventors: Xiaoxiao CHEN, Beijing (CN); Ning ZHU, Beijing (CN); Yun LI, Beijing (CN); Chao WANG, Beijing (CN); Yan ZHOU, Beijing (CN)

(73) Assignees: WUHAN BOE OPTOELECTRONICS TECHNOLOGY CO., LTD., Wuhan, Hubei (CN); BOE TECHNOLOGY GROUP CO., LTD., Beijing (CN)

(21) Appl. No.: 19/146,904

(22) PCT Filed: Jun. 14, 2024
(86) PCT No.: PCT/CN2024/099096

§ 371 Date: Jul. 9, 2025

(30) Foreign Application Priority Data
Jul. 28, 2023 (CN) 202310942940.1

(51) Int. Cl. H10D 86/40; H10D 86/60

(52) U.S. Cl. CPC H10D 86/441; H10D 86/60

(57) ABSTRACT

An array substrate and a display device are provided. The array substrate includes a display region and a non-display region, the non-display region includes at least one binding sub-region, and the binding sub-region is electrically coupled to a circuit board. The array substrate further includes a driving module arranged in the non-display region, and the circuit board provides a driving control signal for the driving module via the binding sub-region. The at least one binding sub-region includes at least three signal providing regions. The binding sub-region includes a plurality of pad terminals arranged in the at least three signal providing regions, and the pad terminal provides the driving control signal for the driving module via a signal line. According to the present disclosure, through adding signal access points, a temperature of the signal line is reduced.

### CROSS-REFERENCE TO RELATED APPLICATION

This application claims a priority of the Chinese patent application No. 202310942940.1 filed on Jul. 28, 2023, which is incorporated herein by reference in its entirety.

### TECHNICAL FIELD

The present disclosure relates to the field of display technology, in particular to an array substrate and a display device.

### BACKGROUND

In a conventional borderless screen display product, a driving module includes a plurality of cascaded driving circuits arranged in a first direction. In the related art, a non-display region includes at least one binding sub-region, and the at least one binding sub-region may be arranged in the first direction. The at least one binding sub-region includes two signal providing regions, a first signal providing region is arranged at a left end of a leftmost binding sub-region, and a second signal providing region is arranged at a right end of a rightmost binding sub-region. Hence, a signal line of the driving circuit in the middle for receiving a driving control signal is relatively long, and its temperature is high, resulting in an abnormality of the driving circuit or high-temperature gravity mura in a display panel, thereby adversely affecting a display effect.

### SUMMARY

In one aspect, the present disclosure provides in some embodiments an array substrate, including a display region and a non-display region. The non-display region includes at least one binding sub-region, and the binding sub-region is electrically coupled to a circuit board. The array substrate further includes a driving module arranged in the non-display region, and the circuit board provides a driving control signal for the driving module via the binding sub-region; the at least one binding sub-region includes at least three signal providing regions; and the at least one binding sub-region includes a plurality of pad terminals arranged in the at least three signal providing regions, and the pad terminal provides the driving control signal for the driving module via a signal line.

In a possible embodiment of the present disclosure, the non-display region includes a plurality of binding sub-regions; the plurality of pad terminals is arranged in a first direction; the binding sub-region includes a first signal providing region and a second signal providing region; the plurality of pad terminals includes a plurality of first pad terminals and a plurality of second pad terminals; the first pad terminal corresponds to the first signal providing region, and the second pad terminal corresponds to the second signal providing region; and the first pad terminal and the second pad terminal are arranged at two opposite sides of the binding sub-region.

In a possible embodiment of the present disclosure, the array substrate further includes a data line, and at least a portion of the data line is arranged in the display region; the plurality of pad terminals further includes a plurality of third pad terminals; the third pad terminal is arranged between the first pad terminal and the second pad terminal; and the third pad terminal is electrically coupled to the data line and configured to apply a data voltage to the data line.

In a possible embodiment of the present disclosure, the driving control signal includes at least one of a clock signal, a common electrode voltage signal, a direct-current voltage signal, or a frame start signal.

In a possible embodiment of the present disclosure, the signal line is configured to provide a clock signal for the driving module; the non-display region includes a first binding sub-region and a second binding sub-region; the array substrate further includes at least one clock signal line arranged between the driving module and the binding sub-region and extending in the first direction; the clock signal line includes a first end and a second end arranged opposite to each other; a first signal providing region of the first binding sub-region is arranged at a first end of the first binding sub-region, and a second signal providing region of the first binding sub-region is arranged at a second end of the first binding sub-region; a first signal providing region of the second binding sub-region is arranged at a first end of the second binding sub-region, and a second signal providing region of the second binding sub-region is arranged at a second end of the first binding sub-region; and the first end of the first binding sub-region is close to the first end of the clock signal line, and the second end of the second binding sub-region is close to the second end of the clock signal line.

In a possible embodiment of the present disclosure, the clock signal line is arranged at a first metal layer; the first binding sub-region is electrically coupled to the clock signal line via a signal line arranged in the second signal providing region of the first binding sub-region and formed at a second metal layer; the second binding sub-region is electrically coupled to the clock signal line via a signal line arranged in the first signal providing region of the second binding sub-region and formed at the second metal layer; and the first metal layer and the second metal layer are different metal layers.

In a possible embodiment of the present disclosure, the first binding sub-region is electrically coupled to the clock signal line via a signal line arranged in the first signal providing region of the first binding sub-region and formed at the first metal layer; and the second binding sub-region is electrically coupled to the clock signal line via a signal line arranged in the second signal providing region of the second binding sub-region and formed at the first metal layer.

In a possible embodiment of the present disclosure, the non-display region includes M binding sub-regions arranged in a first direction, where M is an integer greater than or equal to 3; the plurality of pad terminals is arranged in the first direction; and the signal providing region of the binding sub-region is arranged at a first end or a second end of the binding sub-region.

In a possible embodiment of the present disclosure, the signal line is configured to provide a clock signal for the driving module; the array substrate further includes at least one clock signal line arranged between the driving module and the binding sub-region and extending in the first direction; the clock signal line includes a first end and a second end; a signal providing region of a first binding sub-region is arranged at a first end of the first binding sub-region, and a signal providing region of an M^{th} binding sub-region is arranged at a second end of the M^{th} binding sub-English region; a signal providing region of an m^{th} binding sub-region is arranged at a first end or a second end of the m^{th} binding sub-region, where m is an integer greater than 1 and smaller than M; and the first end of the first binding sub-region is close to the first end of the clock signal line, and the second end of the M^{th} binding sub-region is close to the second end of the clock signal line.

In a possible embodiment of the present disclosure, the non-display region includes one binding sub-region; the plurality of pad terminals is arranged in a first direction; the binding sub-region includes N signal providing regions, where N is an integer greater than or equal to 3; and two signal providing regions of the N signal providing regions are arranged at two opposite sides of the binding sub-region, and the remaining signal providing regions of the N signal providing regions other than the two signal providing regions are arranged in the middle of the binding sub-region.

In a possible embodiment of the present disclosure, the signal line is configured to provide a clock signal for the driving module; the array substrate further includes at least one clock signal line arranged between the driving module and the binding sub-region and extending in the first direction; the clock signal line includes a first end and a second end; and a first signal providing region of the binding sub-region is arranged at a first end of the binding sub-region, an N^{th} signal providing region of the binding sub-region is arranged at a second end of the binding sub-region, and an n^{th} signal providing region of the binding sub-region is arranged in the middle of the binding sub-region, where n is an integer greater than 1 and smaller than N.

In a possible embodiment of the present disclosure, the non-display region includes a first non-display region arranged at a first side of the display region; and the clock signal line, the driving module and the binding sub-region are arranged in the first non-display region.

In a possible embodiment of the present disclosure, the signal line includes at least two signal line portions electrically coupled to each other; and the at least two signal line portions are formed at different metal layers.

In a possible embodiment of the present disclosure, the array substrate further includes a first metal layer and a second metal layer; the signal line includes a first signal line portion and a second signal lien portion; and the first signal line portion is formed at the first metal layer, and the second signal line portion is formed at the second metal layer.

In a possible embodiment of the present disclosure, the array substrate further includes a base substrate, a conductive layer, a first insulation layer arranged between the first metal layer and the second metal layer, and a second insulation layer arranged between the second metal layer and the conductive layer; the first signal line portion is electrically coupled to the second signal line portion via a conductive pattern formed at the conductive layer and a through-hole passing through the second insulation layer; and the first metal layer, the second metal layer and the conductive layer are arranged sequentially in a direction away from the base substrate.

In a possible embodiment of the present disclosure, the array substrate further includes a base substrate, and an orthogonal projection of the first signal line portion onto the base substrate at least partially overlaps with an orthogonal projection of the second signal line portion onto the base substrate.

In a possible embodiment of the present disclosure, the plurality of pad terminals includes a first pad terminal for providing a clock signal and a third pad terminal for providing a data voltage; the first pad terminal includes at least one first sub-pad and at least one second sub-pad; the third pad terminal includes at least one third sub-pad; the first sub-pad includes a first sub-pad portion formed at the first metal layer and a second sub-pad portion formed at the second metal layer; the second sub-pad includes a third sub-pad portion formed at the first metal layer; and the third sub-pad includes a fourth sub-pad portion formed at the first metal layer.

In a possible embodiment of the present disclosure, the driving module includes a plurality of levels of driving circuits; the driving circuit includes an output transistor; a gate electrode of the output transistor is electrically coupled to a first node, a first electrode of the output transistor is electrically coupled to a clock signal line, and a second electrode of the output transistor is electrically coupled to a driving signal output end; and a width-to-length ratio of a channel of the output transistor is smaller than a first width-to-length ratio threshold.

In a possible embodiment of the present disclosure, the driving circuit further includes an output resetting transistor; a gate electrode of the output resetting transistor is electrically coupled to a resetting end, a first electrode of the output resetting transistor is electrically coupled to the driving signal output end, and a second electrode of the output resetting transistor is electrically coupled to a first voltage end; and a width-to-length ratio of a channel of the output resetting transistor is greater than a second width-to-length ratio threshold.

In a possible embodiment of the present disclosure, the signal line is configured to transmit a clock signal; and a rising edge of the clock signal includes at least two steps.

In another aspect, the present disclosure provides in some embodiments a display device including a circuit board and the above-mentioned array substrate. The circuit board is electrically coupled to a binding sub-region of the array substrate, and configured to provide a driving control signal for a driving module of the array substrate via the binding sub-region.

### BRIEF DESCRIPTION OF THE DRAWINGS

FIG. 1A is a schematic view showing an array substrate according to at least one embodiment of the present disclosure;

FIG. 1B is a schematic view showing the array substrate according to at least one embodiment of the present disclosure;

FIG. 1C is an enlarged view of a first binding sub-region Q1 in FIG. 1A;

FIG. 1D is an enlarged view of a second binding sub-region Q2 in FIG. 1A;

FIG. 2A is an oscillogram of a current I0 on a clock signal line during the operation of the array substrate in FIG. 1A;

FIG. 2B is an oscillogram of a current I1 on a clock signal line during the operation of a conventional array substrate;

FIG. 3A is a schematic view showing the array substrate according to at least one embodiment of the present disclosure;

FIG. 3B is a schematic view showing the array substrate according to at least one embodiment of the present disclosure;

FIG. 3C is an enlarged view of the first binding sub-region Q1 and the second binding sub-region Q2 in FIG. 3A;

FIG. 3D is an enlarged view of a third binding sub-region Q3 and a fourth binding sub-region Q4 in FIG. 3A;

FIG. 4A is a schematic view showing the array substrate according to at least one embodiment of the present disclosure;

FIG. 4B is a schematic view showing the array substrate according to at least one embodiment of the present disclosure;

FIG. 4C is an enlarged view of the first binding sub-region Q1 in FIG. 4A;

FIG. 5 is a schematic view showing the layout of six signal lines in the array substrate according to at least one embodiment of the present disclosure;

FIG. 6 is a schematic view showing the layout of a gate metal layer in FIG. 5;

FIG. 7 is a schematic view showing the layout of a source/drain metal layer in FIG. 5;

FIG. 8 is a schematic view showing the layout of a conductive layer in FIG. 5;

FIG. 9 is a sectional view of the array substrate in FIG. 5 along line A-A′;

FIG. 10 is a schematic view showing an actual connection relationship between pad terminals and signal liens;

FIG. 11 is a schematic view showing the layout of the gate metal layer in FIG. 10;

FIG. 12 is a schematic view showing the layout of the source/drain metal layer in FIG. 10;

FIG. 13 is a schematic view showing the layout of the conductive layer in FIG. 10;

FIG. 14 is a schematic view showing an actual connection relationship between signal lines and a GOA module;

FIG. 15 is a circuit diagram of a driving circuit according to at least one embodiment of the present disclosure;

FIG. 16 is an oscillogram of currents on a clock signal line before and after a width-to-length ratio of a channel of an output transistor M3 decreases;

FIG. 17 is a comparative diagram of a width W of the channel of M3 and a current I on the clock signal line;

FIG. 18 is a comparative diagram of the width of the channel of M3 and a fall time Tf of a driving signal;

FIG. 19 is an oscillogram of a clock signal CLK according to at least one embodiment of the present disclosure;

FIG. 20 is an oscillogram of the current I on the clock signal line in a case that a rising edge of the clock signal includes two steps; and

FIG. 21 is an oscillogram of the current I on the clock signal line in a case that the rising edge of the clock signal includes only one step in the related art.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

The present disclosure provides in some embodiments an array substrate, which includes a display region and a non-display region. The non-display region includes at least one binding sub-region, and the binding sub-region is electrically coupled to a circuit board. The array substrate further includes a driving module arranged in the non-display region, and the circuit board provides a driving control signal for the driving module via the binding sub-region; the at least one binding sub-region includes at least three signal providing regions; and the at least one binding sub-region includes a plurality of pad terminals arranged in the at least three signal providing regions, and the pad terminal provides the driving control signal for the driving module via a signal line.

In a conventional borderless screen display product, a driving module includes a plurality of cascaded driving circuits arranged in a first direction. In the related art, a non-display region includes at least one binding sub-region, and the at least one binding sub-region may be arranged in the first direction. The at least one binding sub-region includes two signal providing regions, a first signal providing region is arranged at a left end of a leftmost binding sub-region, and a second signal providing region is arranged at a right end of a rightmost binding sub-region. Hence, a signal line of the driving circuit in the middle for receiving a driving control signal is relatively long, and its temperature is high, resulting in an abnormality of the driving circuit or high-temperature gravity mura in a display panel, thereby adversely affecting a display effect. Based on the above, in the array substrate according to the embodiments of the present disclosure, the non-display region includes at least one binding sub-region, the circuit board provides the driving control signal for the driving module via the binding sub-region, the at least one binding sub-region includes at least three signal providing regions, and the pad terminals in the at least three signal providing regions provide the driving control signal for the driving module via the signal line. Through providing more signal access points, it is able to reduce a temperature of the signal line.

In at least one embodiment of the present disclosure, the first direction is, but not limited to, a row direction, i.e., a horizontal direction.

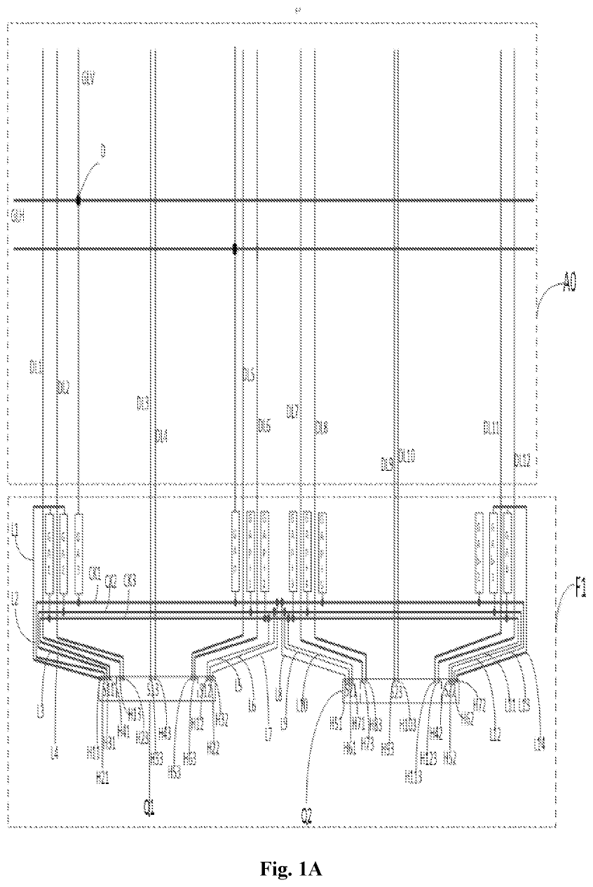

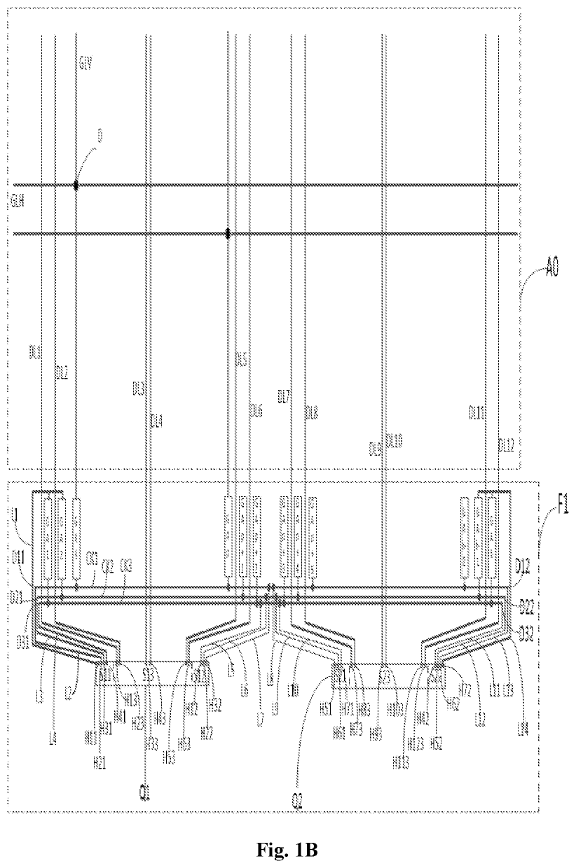

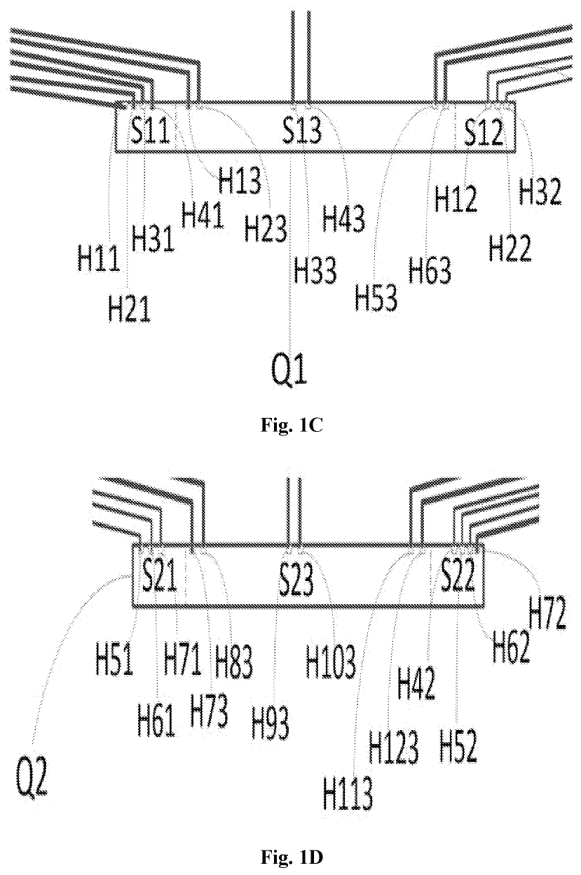

In the borderless screen display product, gate lines extending in the row direction and gate lines extending in a column direction are provided, and the gate line extending in the row direction is electrically coupled to the gate lines extending in the column direction. Referring to FIG. 1, a gate line GLH extending in the row direction is electrically coupled to a gate line GLV extending in the column direction via a connection point D, and a data line extending in the column direction and the gate line extending in the column direction are electrically coupled to a driving module and configured to receive a driving signal generated by the driving module. The driving module includes a plurality of cascaded driving circuits (the driving circuit may be a gate driving circuit).

In a possible embodiment of the present disclosure, the driving control signal includes at least one of a clock signal, a common electrode voltage signal, a direct-current voltage signal, or a frame start signal.

In at least one embodiment of the present disclosure, the driving control signal includes, but not limited to, a ground signal, a power source voltage signal, a common electrode voltage signal, a common electrode feedback voltage signal, a clock signal, a high voltage signal, a first low voltage signal, a second low voltage signal, a frame start signal, an ADD test signal, etc. Principles for generating heat in the signal line by these signals are the same, and as compared with the other signals, the clock signal, as a high-frequency square signal, has a largest impact on the temperature of the signal line for transmitting the clock signal. In at least one embodiment of the present disclosure, the description will be given in a case that the driving control signal is the clock signal.

In a conventional high-resolution, high-refresh-rate display product, due to the limitations of a bezel and a charging rate, a large current flows through the signal line for transmitting the driving control signal, so the temperature of the signal line is high, and such defects as excessive output of the driving circuit and high-temperature black spots of a display panel easily occur.

In at least one embodiment of the present disclosure, the non-display region includes a plurality of binding sub-regions; the plurality of pad terminals is arranged in a first direction; the binding sub-region includes a first signal providing region and a second signal providing region; the plurality of pad terminals includes a plurality of first pad terminals and a plurality of second pad terminals; the first pad terminal corresponds to the first signal providing region, and the second pad terminal corresponds to the second signal providing region; and the first pad terminal and the second pad terminal are arranged at two opposite sides of the binding sub-region.

During the implementation, the non-display region includes a plurality of binding sub-regions, each binding sub-region includes two signal providing regions, the plurality of pad terminals includes the first pad terminal arranged in the first signal providing region and the second pad terminal arranged in the second signal providing region, and the first pad terminal and the second pad terminal are arranged at two opposite sides of the binding sub-region.

In at least one embodiment of the present disclosure, the array substrate further includes a data line, and at least a portion of the data line is arranged in the display region. The plurality of pad terminals further includes a plurality of third pad terminals; the third pad terminal is arranged between the first pad terminal and the second pad terminal; and the third pad terminal is electrically coupled to the data line and configured to apply a data voltage to the data line.

During the implementation, the array substrate further includes the data line extending in a vertical direction, and the third pad terminal between the first pad terminal and the second pad terminal applies the data voltage to the data line.

In at least one embodiment of the present disclosure, the signal line is configured to provide a clock signal for the driving module, and the non-display region includes a first binding sub-region and a second binding sub-region. The array substrate further includes at least one clock signal line arranged between the driving module and the binding sub-region and extending in the first direction. The clock signal line includes a first end and a second end. A first signal providing region of the first binding sub-region is arranged at a first end of the first binding sub-region, and a second signal providing region of the first binding sub-region is arranged at a second end of the first binding sub-region. A first signal providing region of the second binding sub-region is arranged at a first end of the second binding sub-region, and a second signal providing region of the second binding sub-region is arranged at a second end of the first binding sub-region. The first end of the first binding sub-region is close to the first end of the clock signal line, and the second end of the second binding sub-region is close to the second end of the clock signal line.

During the implementation, the non-display region includes two binding sub-regions, and at least one clock signal line extending in the first direction is arranged between the driving module and the binding sub-region. The first signal providing region of the first binding sub-region is arranged at the first end of the first binding sub-region, and the second signal providing region of the first binding sub-region is arranged at the second end of the first binding sub-region. The first signal providing region of the second binding sub-region is arranged at the first end of the second binding sub-region, and the second signal providing region of the second binding sub-region is arranged at the second end of the second binding sub-region. The first end of the first binding sub-region is close the first end of the clock signal line, and the second end of the second binding sub-region is close to the second end of the clock signal line.

In a possible embodiment of the present disclosure, in a case that the first direction is a horizontal direction, the first end is a left end, and the second end is a right end. However, the present disclosure is not limited thereto.

In at least one embodiment of the present disclosure, the clock signal line is arranged at a first metal layer; the first binding sub-region is electrically coupled to the clock signal line via a signal line arranged in the second signal providing region of the first binding sub-region and formed at a second metal layer; the second binding sub-region is electrically coupled to the clock signal line via a signal line arranged in the first signal providing region of the second binding sub-region and formed at the second metal layer; and the first metal layer and the second metal layer are different metal layers.

During the implementation, the first binding sub-region is electrically coupled to the clock signal line via the signal line arranged in the second signal providing region of the first binding sub-region and at a layer different from the clock signal line, and the second binding sub-region is electrically coupled to the clock signal line arranged in the first signal providing region of the second binding sub-region and at a layer different from the clock signal line, so as to prevent the occurrence of a short circuit between the signal line and the clock signal line at an intersection.

In at least one embodiment of the present disclosure, the first binding sub-region is electrically coupled to the clock signal line via a signal line arranged in the first signal providing region of the first binding sub-region and formed at the first metal layer; and the second binding sub-region is electrically coupled to the clock signal line via a signal line arranged in the second signal providing region of the second binding sub-region and formed at the first metal layer.

During the implementation, at an edge, the first binding sub-region is electrically coupled to the clock signal line via the signal line arranged in the first signal providing region of the first binding sub-region and at a same layer as the clock signal line, and the second binding sub-region is electrically coupled to the clock signal line via the signal line arranged in the second signal providing region of the second binding sub-region and at a same layer as the clock signal line, so as to facilitate the electrical connection between the signal line and the clock signal line.

In a possible embodiment of the present disclosure, the first metal layer is, but not limited to, a gate metal layer, and the second metal layer is, but not limited to, a source/drain metal layer.

As shown in FIG. 1A, in at least one embodiment of the present disclosure, the array substrate includes a display region A0 and a non-display region, and the non-display region includes a first non-display region F1 arranged at a first side of the display region A0.

The array substrate includes a driving module, a first binding sub-region Q1 and a second binding sub-region Q2, and the driving module includes a plurality of levels of driving circuits arranged in the first direction. S11 represents a first signal providing region of the first binding sub-region Q1, S12 represents a second signal providing region of the first binding sub-region Q1, and S13 represents a third signal providing region of the first binding sub-region Q1. S21 represents a first signal providing region of the second binding sub-region Q2, S22 represents a second signal providing region of the second binding sub-region Q2, and S23 represents a third signal providing region of the second binding sub-region Q2. S11 is arranged at a left end of Q1, S12 is arranged at a right end of Q1, and S13 is arranged between S11 and S12, i.e., S11 and S12 are arranged at two opposite sides of S13. S21 is arranged at a left end of Q2, S22 is arranged at a right end of Q2, and S23 is arranged between S21 and S22, i.e., S21 and S22 are arranged at two opposite sides of S23.

In at least one embodiment of the present disclosure, the array substrate includes a first one of first pad terminals H11, a second one of first pad terminals H21, a third one of first pad terminals H31, and a fourth one of first pad terminals H41 arranged in S11. The array substrate further includes a fifth one of first pad terminals H51, a sixth one of first pad terminals H61 and a seventh one of first pad terminals H71 arranged in S21. The array substrate further includes a first one of second pad terminals H12, a second one of second pad terminals H22 and a third one of second pad terminals H32 arranged in S12. The array substrate further includes a fourth one of second pad terminals H42, a fifth one of second pad terminals H52, a sixth one of second pad terminals H62 and a seventh one of second pad terminals H72 arranged in S22.

The array substrate further includes a first one of third pad terminals H13, a second one of third pad terminals H23, a third one of third pad terminals H33, a fourth one of third pad terminals H43, a fifth one of third pad terminals H53, and a sixth one of third pad terminals H63 arranged in S13. The array substrate further includes a seventh one of third pad terminals H73, an eighth one of third pad terminals H83, a ninth one of third pad terminals H93, a tenth one of third pad terminals H103, an eleventh one of third pad terminals H113, and a twelfth one of third pad terminals H123 arranged in S23.

In FIG. 1A, GA1 represents a first-level driving circuit of the driving module, GA2 represents a second-level driving circuit of the driving module, GA3 represents a third-level driving circuit of the driving module, GAp represents a p^{th}-level driving circuit of the driving module, GAp+1 represents a (p+1)^{th}-level driving circuit of the driving module, GAp+2 represents a (p+2)^{th}-level driving circuit of the driving module, GAp+3 represents a (p+3)^{th}-level driving circuit of the driving module, GAp+4 represents a (p+4)^{th}-level driving circuit of the driving module, GAp+5 represents a (p+5)^{th}-level driving circuit of the driving module, GAb−2 represents a (b−2)^{th}-level driving circuit of the driving module, GAb−1 represents a (b−1)^{th}-level driving circuit of the driving module, and GAb represents a b^{th}-level driving circuit of the driving module, where p and b are both positive integers.

In at least one embodiment as shown in FIG. 1A, CK1 represents a first clock signal line, CK2 represents a second clock signal line, and CK3 represents a third clock signal line. The clock signal lines are all arranged at a gate metal layer, and CK1, CK2 and CK3 extend in a horizontal direction. The pad terminals are arranged in the horizontal direction.

DL1 represents a first data line, DL2 represents a second data line, DL3 represents a third data line, DL4 represents a fourth data line, DL5 represents a fifth data line, DL6 represents a sixth data line, DL7 represents a seventh data line, DL8 represents an eighth data line, DL9 represents a ninth data line, DL10 represents a tenth data line, DL11 represents an eleventh data line, and DL12 represents a twelfth data line. The data lines are all arranged at a source/drain metal layer.

In at least one embodiment as shown in FIG. 1A, H11 is directly electrically coupled to GA1 via a first signal line L1 arranged at the gate metal layer, or H11 is electrically coupled to GA1 and GA2 via the first signal line arranged at the gate metal layer, so as to provide an initial triggering signal (STV signal) for the driving circuit. H21 is electrically coupled to a left end of CK1 via a second signal line L2 arranged at the gate metal layer, H31 is electrically coupled to a left end of CK2 via a third signal line L3 arranged at the gate metal layer, and H41 is electrically coupled to a left end of CK3 via a fourth signal line L4 arranged at the gate metal layer, so as to provide a clock signal.

H12 is electrically coupled to CK3 via a fifth signal line L5 arranged at the source/drain metal layer, H22 is electrically coupled to CK2 via a sixth signal line L6 arranged at the source/drain metal layer, and H32 is electrically coupled to CK1 via a seventh signal line L7 arranged at the source/drain metal layer.

H51 is electrically coupled to CK3 via an eighth signal line L8 arranged at the source/drain metal layer, H61 is electrically coupled to CK2 via a ninth signal line L9 arranged at the source/drain metal layer, and H71 is electrically coupled to CK1 via a tenth signal line L10 arranged at the source/drain metal layer.

H42 is electrically coupled to a right end of CK3 via an eleventh signal line L11 arranged at the gate metal layer, H52 is electrically coupled to a right end of CK2 via a twelfth signal line L12 arranged at the gate metal layer, H62 is electrically coupled to a right end of CK1 via a thirteenth signal line L13 arranged at the gate metal layer, so as to provide a clock signal. H72 is directly electrically coupled to GAb via a fourteenth signal line L14 arranged at the gate metal layer, or H72 is electrically coupled to GAb−1 and GAb simultaneously via the fourteenth signal line L14 arranged at the gate metal layer, so as to provide an initial triggering signal. In a possible embodiment of the present disclosure, the driving circuits at two ends of the driving module receive the initial triggering signal so as to perform bidirectional scanning, or only the driving circuit at one end of the driving module receives the initial triggering signal so as to perform unidirectional scanning, which will not be particularly defined herein.

H13 is electrically coupled to DL1, H23 is electrically coupled to DL2, H33 is electrically coupled to DL3, H43 is electrically coupled to DL4, H53 is electrically coupled to DL5, H63 is electrically coupled to DL6, H73 is electrically coupled to DL7, H83 is electrically coupled to DL8, H93 is electrically coupled to DL9, H103 is electrically coupled to DL10, H113 is electrically coupled to DL11, and H123 is electrically coupled to DL12.

In the array substrate in FIG. 1A, the driving module, CK1, CK2, CK3 and the binding sub-regions are all arranged in the first non-display region F1, so as to achieve a full-screen display effect.

As shown in FIG. 1B, on the basis of FIG. 1A, a first end and a second end of each clock signal line are marked. The first end is a left end, and the second end is a right end. In FIG. 1B, D11 represents a first end of CK1, D12 represents a second end of CK1, D21 represents a first end of CK2, D22 represents a second end of CK2, D31 represents a first end of CK3, and D32 represents a second end of CK3.

FIG. 1C is an enlarged view of the first binding sub-region Q1 in FIG. 1A, and FIG. 1D is an enlarged view of the second binding sub-region Q2 in FIG. 1A.

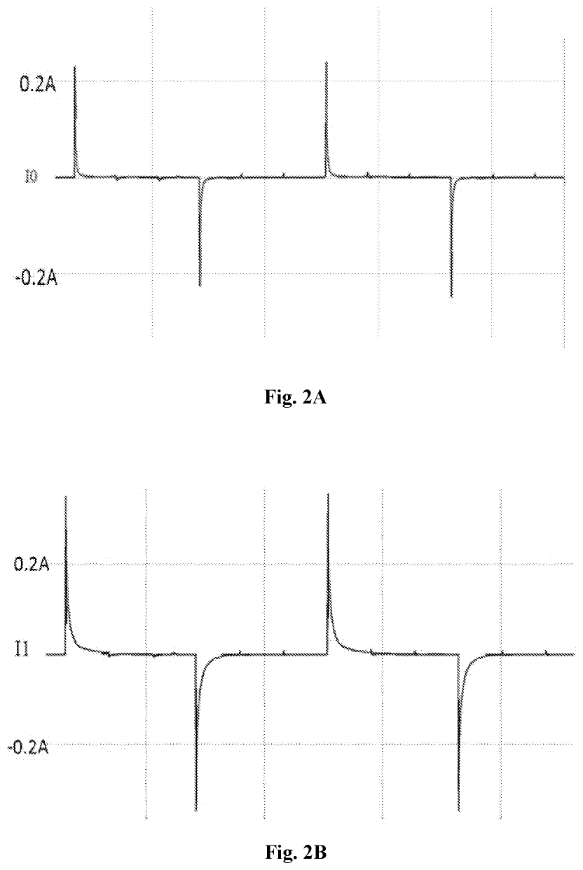

FIG. 2A is an oscillogram of a current I0 on a clock signal line during the operation of the array substrate in FIG. 1A, and FIG. 2B is an oscillogram of a current I1 on a clock signal line during the operation of a conventional array substrate.

After comparison, a value of the current I0 on the clock signal line during the operation of the array substrate in FIG. 1A is smaller than a value of the current I1 on the clock signal line during the operation of the conventional array substrate.

In at least one embodiment of the present disclosure, the non-display region includes M binding sub-regions arranged in a first direction, where M is an integer greater than or equal to 3. The array substrate includes a plurality of pad terminals arranged in the binding sub-regions, and the plurality of pad terminals is arranged in the first direction. The signal providing region of the binding sub-region is arranged at a first end or a second end of the binding sub-region.

During the implementation, the non-display region includes at least three binding sub-regions arranged in the first direction, and the signal providing region of each binding sub-region is arranged at the first end or the second end of the binding sub-region.

In at least one embodiment of the present disclosure, the signal line is configured to provide a clock signal for the driving module; the array substrate further includes at least one clock signal line arranged between the driving module and the binding sub-region and extending in the first direction; the clock signal line includes a first end and a second end arranged opposite to each other; a signal providing region of a first binding sub-region is arranged at a first end of the first binding sub-region, and a signal providing region of an M^{th} binding sub-region is arranged at a second end of the M^{th} binding sub-region; a signal providing region of an m^{th} binding sub-region is arranged at a first end or a second end of the m^{th} binding sub-region, where m is an integer greater than 1 and smaller than M; and the first end of the first binding sub-region is close to the first end of the clock signal line, and the second end of the M^{th} binding sub-region is close to the second end of the clock signal line.

In a possible embodiment of the present disclosure, the first end is a left end, and the second end is a right end.

During the implementation, in a case that the non-display region includes at least three binding sub-regions arranged in the first direction (the first direction may be a horizontal direction), the signal providing region of the leftmost first binding sub-region is arranged at the left end of the first binding sub-region, the signal providing region of the rightmost M^{th} binding sub-region is arranged at the right end of the M^{th} binding sub-region, the m^{th} binding sub-region is arranged between the first binding sub-region and the M^{th} binding sub-region, the signal providing region of the m^{th} binding sub-region is arranged at the left end or the right end of the m^{th} binding sub-region, the left end of the first binding sub-region is close to the left end of the clock signal line, and the right end of the M^{th} binding sub-region is close to the right end of the clock signal line.

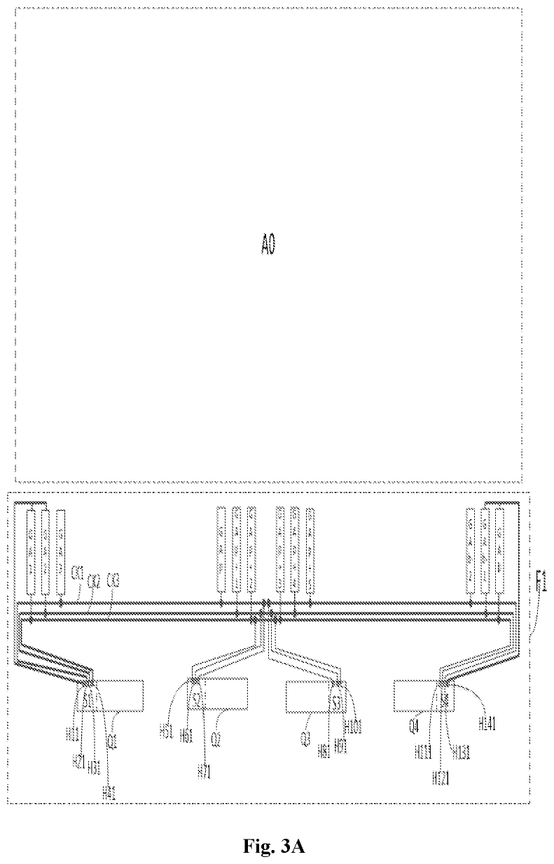

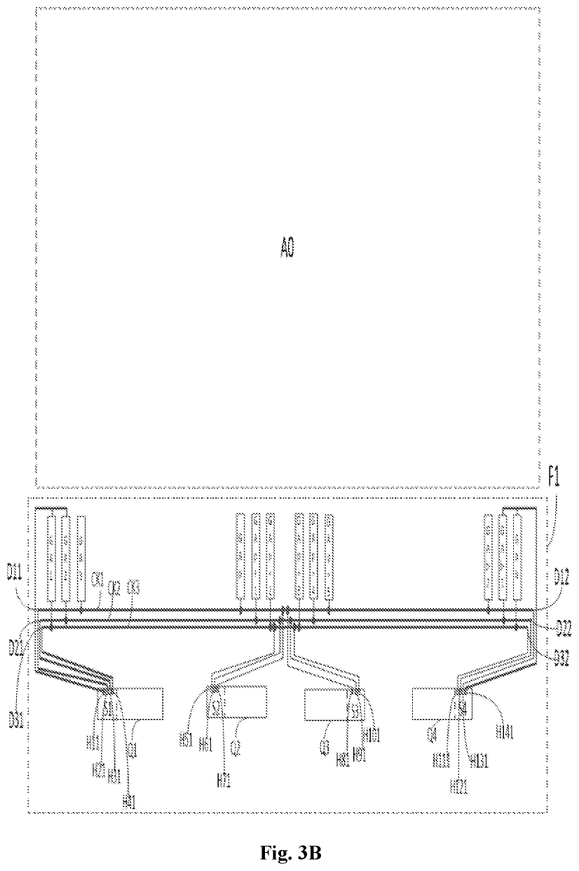

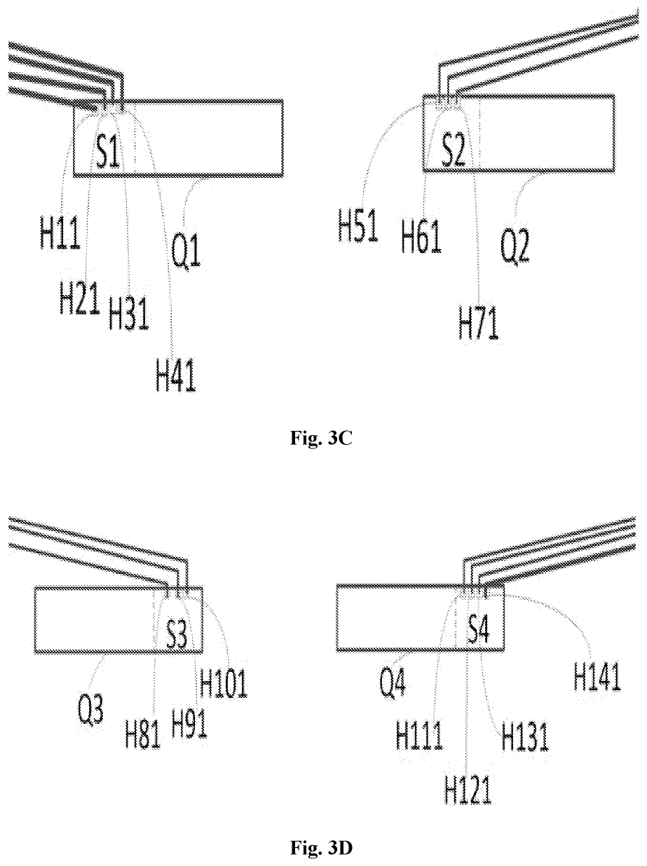

As shown in FIG. 3A, the array substrate in at least one embodiment of the present disclosure includes a display region A0 and a non-display region, and the non-display region includes a first non-display region F1 arranged at a first side of the display region A0.

The array substrate includes a driving module, a first binding sub-region Q1, a second binding sub-region Q2, a third binding sub-region Q3 and a fourth binding sub-region Q4. Each binding sub-region includes one signal providing region. The driving module includes a plurality of levels of driving circuits arranged in a first direction.

S1 represents a signal providing region of the first binding sub-region Q1, S2 represents a signal providing region of the second binding sub-region Q2, S3 represents a signal providing region of the third binding sub-region Q3, and S4 represents a signal providing region of the fourth binding sub-region Q4. S1 is arranged at the left end of Q1, S2 is arranged at the left end of Q2, S3 is arranged at the right end of Q3, and S4 is arranged at the right end of Q4.

In FIG. 3A, GA1 represents a first-level driving circuit of the driving module, GA2 represents a second-level driving circuit of the driving module, GA3 represents a third-level driving circuit of the driving module, GAp represents a p^{th}-level driving circuit of the driving module, GAp+1 represents a (p+1)^{th}-level driving circuit of the driving module, GAp+2 represents a (p+2)^{th}-level driving circuit of the driving module, GAp+3 represents a (p+3)^{th}-level driving circuit of the driving module, GAp+4 represents a (p+4)^{th}-level driving circuit of the driving module, GAp+5 represents a (p+5)^{th}-level driving circuit of the driving module, GAb−2 represents a (b−2)^{th}-level driving circuit of the driving module, GAb−1 represents a (b−1)^{th}-level driving circuit of the driving module, and GAb represents a b^{th}-level driving circuit of the driving module, where p and b are both positive integers.

In at least one embodiment as shown in FIG. 3A, CK1 represents a first clock signal line, CK2 represents a second clock signal line, and CK3 represents a third clock signal line. The clock signal lines are all arranged at a gate metal layer, and CK1, CK2 and CK3 extend in a horizontal direction. The pad terminals are arranged in the horizontal direction.

In FIG. 3A, H11 represents a first one of first pad terminals, H21 represents a second one of first pad terminals, H31 represents a third one of first pad terminals, H41 represents a fourth one of first pad terminals, H51 represents a fifth one of first pad terminals, H61 represents a sixth one of first pad terminals, H71 represents a seventh one of first pad terminals, H81 represents an eighth one of first pad terminals, H91 represents a ninth one of first pad terminals, H101 represents a tenth one of first pad terminals, H111 represents an eleventh one of first pad terminals, H121 represents a twelfth one of first pad terminals, H131 represents a thirteenth one of first pad terminals, and H141 represents a fourteenth one of first pad terminals.

H11, H21, H31 and H41 are arranged in S1, H51, H61 and H71 are arranged in S2, H81, H91 and H101 are arranged in S3, and H111, H121, H131 and H141 are arranged in S4. H11 is directly electrically coupled to GA1 and GA2, and configured to provide a clock signal. H21 is electrically coupled to the left end of CK1, H31 is electrically coupled to the left end of CK2, and H41 is electrically coupled to the left end of CK3. H51 is electrically coupled to a middle portion of CK3, H61 is electrically coupled to a middle portion of CK2, and H71 is electrically coupled to the middle portion of CK3. H81 is electrically coupled to the middle portion of CK3, H91 is electrically coupled to the middle portion of CK2, and H101 is electrically coupled to the middle portion of CK3. H111 is electrically coupled to the right end of CK3, H121 is electrically coupled to the right end of CK2, H131 is electrically coupled to the right end of CK1, and H141 is directly electrically coupled to GAb−1 and GAb, so as to provide a clock signal.

In the array substrate in FIG. 3A, the driving module, CK1, CK2, CK3 and the binding sub-regions are all arranged at the first non-display region F1.

As shown in FIG. 3B, on the basis of FIG. 3A, the first end and the second end of each clock signal are shown. The first end is a left end, and the second end is a right end.

In FIG. 3B, D11 represents the first end of CK1, D12 represents the second end of CK1, D21 represents the first end of CK2, D22 represents the second end of CK2, D31 represents the first end of CK3, and D32 represents the second end of CK3.

FIG. 3C is an enlarged view of the first binding sub-region Q1 and the second binding sub-region Q2 in FIG. 3A, and FIG. 3D is an enlarged view of the third binding sub-region Q3 and the fourth binding sub-region Q4.

In at least one embodiment as shown in FIG. 3A, the quantity of binding sub-region is an even number, the pad terminal in the leftmost binding sub-region for providing the clock signal is extracted from the left end of the binding sub-region, and the pad terminal in the rightmost binding sub-region for providing the clock signal is extracted from the right end of the binding sub-region. The binding sub-regions in the middle are divided into two groups. The pad terminal in the binding sub-region close to the leftmost binding sub-region for providing the clock signal is extracted from the left end of the binding sub-region, and the pad terminal in the binding sub-region close to the rightmost binding sub-region for providing the clock signal is extracted from the right end of the binding sub-region. In other words, the binding sub-regions and the pad terminals are arranged symmetrically relative to a central line of the array substrate.

In at least one embodiment of the present disclosure, the quantity of binding sub-regions may be an even number or an odd number. The pad terminal in the leftmost binding sub-region for providing the clock signal is extracted from the left end of the binding sub-region, and the pad terminal in the rightmost binding sub-region for providing the clock signal is extracted from the right end of the binding sub-region. A part of the pad terminals in the middle binding sub-region for providing the clock signal are extracted from the left end of the binding sub-region and the other part of the pad terminals are extracted from the right end of the binding sub-region, or the pad terminals in the middle binding sub-region for providing the clock signal are all extracted from the left end or the right end of the binding sub-region.

In at least one embodiment of the present disclosure, the quantity of binding sub-regions may be an even number or an odd number. The pad terminal in the leftmost binding sub-region for providing the clock signal is extracted from the left end of the binding sub-region, the pad terminal in the rightmost binding sub-region for providing the clock signal is extracted from the right end of the binding sub-region, and the pad terminal in the middle binding sub-region for providing the clock signal is extracted from both the left end and the right end of the binding sub-region.

In at least one embodiment of the present disclosure, the quantity of binding sub-regions may be an even number or an odd number. The pad terminal in the leftmost binding sub-region for providing the clock signal is extracted from the left end of the binding sub-region, and the pad terminal in the rightmost binding sub-region for providing the clock signal is extracted from the right end of the binding sub-region. The pad terminals in a part of the middle binding sub-regions for providing the clock signal are extracted from both the left end and the right end of each binding sub-region and the pad terminals in the other part of the middle binding sub-regions for providing the clock signal are extracted from the left end or the right end of each binding sub-region.

In at least one embodiment of the present disclosure, the non-display region includes one binding sub-region, the array substrate includes a plurality of pad terminals arranged in the binding sub-region, and the plurality of pad terminals is arranged in the first direction. The binding sub-region includes N signal providing regions, where N is an integer greater than or equal to 3. Two signal providing regions of the N signal providing regions are arranged at two opposite sides of the binding sub-region, and the remaining signal providing regions of the N signal providing regions other than the two signal providing regions are arranged in the middle of the binding sub-region.

During the implementation, the non-display region includes one binding sub-region, and the binding sub-region includes at least three signal providing regions arranged in the first direction.

In at least one embodiment of the present disclosure, the signal line is configured to provide a clock signal for the driving module; the array substrate further includes at least one clock signal line arranged between the driving module and the binding sub-region and extending in the first direction; the clock signal line includes a first end and a second end; and a first signal providing region of the binding sub-region is arranged at a first end of the binding sub-region, an Nₜₕ signal providing region of the binding sub-region is arranged at a second end of the binding sub-region, and an n^{th} signal providing region of the binding sub-region is arranged in the middle of the binding sub-region, where n is an integer greater than 1 and smaller than N.

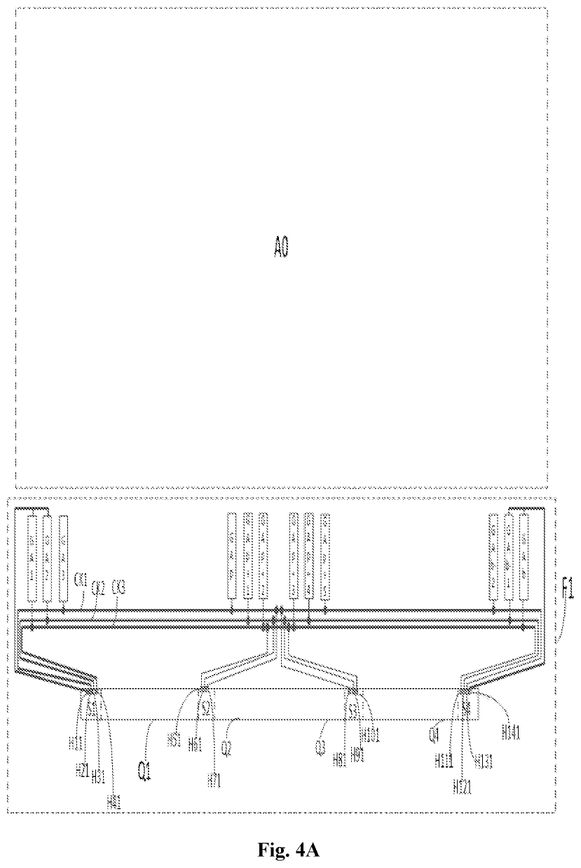

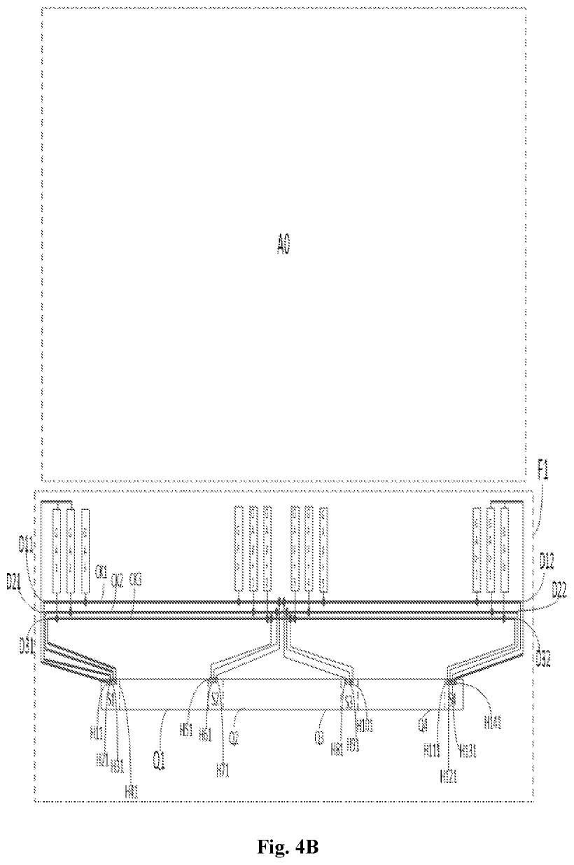

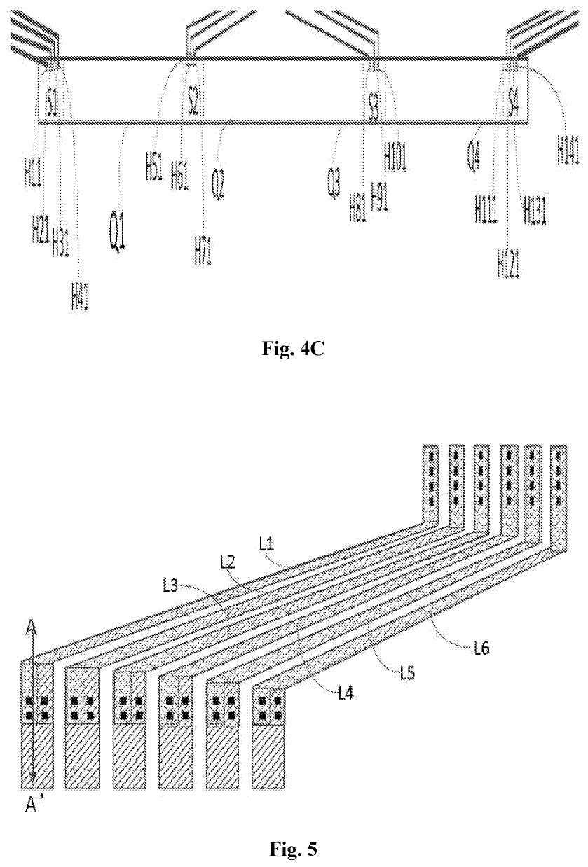

As shown in FIG. 4A, the array substrate in at least one embodiment of the present disclosure includes a display region A0 and a non-display region, and the non-display region includes a first non-display region F1 arranged at a first side of the display region A0.

The array substrate includes a driving module and a first binding sub-region Q1, the first binding sub-region includes four signal providing regions, and the driving module includes a plurality of levels of driving circuits arranged in the first direction.

S1 represents a first signal providing region of the first binding sub-region Q1, S2 represents a second signal providing region of the first binding sub-region Q1, S3 represents a third signal providing region of the first binding sub-region Q1, and S4 represents a fourth signal providing region of the first binding sub-region Q1. S1 is arranged at a left end of Q1, S2 and S3 are arranged between S1 and S4, and S4 is arranged at a right end of Q1.

In FIG. 4A, GA1 represents a first-level driving circuit of the driving module, GA2 represents a second-level driving circuit of the driving module, GA3 represents a third-level driving circuit of the driving module, GAp represents a p^{th}-level driving circuit of the driving module, GAp+1 represents a (p+1)^{th}-level driving circuit of the driving module, GAp+2 represents a (p+2)^{th}-level driving circuit of the driving module, GAp+3 represents a (p+3)^{th}-level driving circuit of the driving module, GAp+4 represents a (p+4)^{th}-level driving circuit of the driving module, GAp+5 represents a (p+5)^{th}-level driving circuit of the driving module, GAb−2 represents a (b−2)^{th}-level driving circuit of the driving module, GAb−1 represents a (b−1)^{th}-level driving circuit of the driving module, and GAb represents a b^{th}-level driving circuit of the driving module, where p and b are both positive integers.

In at least one embodiment as shown in FIG. 4A, CK1 represents a first clock signal line, CK2 represents a second clock signal line, and CK3 represents a third clock signal line. The clock signal lines are all arranged at a gate metal layer, and CK1, CK2 and CK3 extend in a horizontal direction. The pad terminals are arranged in the horizontal direction.

In FIG. 4A, H11 represents a first one of first pad terminals, H21 represents a second one of first pad terminals, H31 represents a third one of first pad terminals, H41 represents a fourth one of first pad terminals, H51 represents a fifth one of first pad terminals, H61 represents a sixth one of first pad terminals, H71 represents a seventh one of first pad terminals, H81 represents an eighth one of first pad terminals, H91 represents a ninth one of first pad terminals, H101 represents a tenth one of first pad terminals, H111 represents an eleventh one of first pad terminals, H121 represents a twelfth one of first pad terminals, H131 represents a thirteenth one of first pad terminals, and H141 represents a fourteenth one of first pad terminals.

H11, H21, H31 and H41 are arranged in S1, H51, H61 and H71 are arranged in S2, H81, H91 and H101 are arranged in S3, and H111, H121, H131 and H141 are arranged in S4. H11 is directly electrically coupled to GA1 and GA2, and configured to provide a clock signal. H21 is electrically coupled to a left end of CK1, H31 is electrically coupled to a left end of CK2, and H41 is electrically coupled to a left end of CK3. H51 is electrically coupled to a middle portion of CK3, H61 is electrically coupled to a middle of CK2, and H71 is electrically coupled to the middle portion of CK3. H81 is electrically coupled to the middle portion of CK3, H91 is electrically coupled to the middle portion of CK2, and H101 is electrically coupled to the middle portion of CK3. H111 is electrically coupled to a right end of CK3, H121 is electrically coupled to a right end of CK2, H131 is electrically coupled to a right end of CK1, and H141 is directly electrically coupled to GAb−1 and GAb, so as to provide a clock signal.

In the array substrate in FIG. 4A, the driving module, CK1, CK2, CK3 and the binding sub-regions are all arranged in the first non-display region F1.

As shown in FIG. 4B, on the basis of FIG. 4A, the first end and the second end of each clock signal end are shown. The first end is a left end, and the second end is a right end.

In FIG. 4B, D11 represents the first end of CK1, D12 represents the second end of CK1, D21 represents the first end of CK2, D22 represents the second end of CK2, D31 represents the first end of CK3, and D32 represents the second end of CK3.

FIG. 4C is an enlarged view of the first binding sub-region Q1 in FIG. 4A.

In at least one embodiment of the present disclosure, the non-display region includes a first non-display region arranged at a first side of the display region; and the clock signal line, the driving module and the binding sub-region are arranged in the first non-display region.

In at least one embodiment of the present disclosure, the signal line includes at least two signal line portions electrically coupled to each other, and the at least two signal line portions are formed at different metal layers.

During the implementation, thermal power of the signal line is derived from a current flowing through the signal line and a square resistance per unit length. In the related art, the signal line is a single-layered line. However, in at least one embodiment of the present disclosure, the signal line includes at least two signal line portions electrically coupled to each other, and the at least two signal line portions are formed at different metal layers, so as to reduce a resistance of the signal line, and reduce the thermal power, thereby to reduce a temperature of the signal line.

In a possible embodiment of the present disclosure, the array substrate includes a first metal layer and a second metal layer; the signal line includes a first signal line portion and a second signal lien portion; and the first signal line portion is formed at the first metal layer, and the second signal line portion is formed at the second metal layer.

In at least one embodiment of the present disclosure, the array substrate further includes a base substrate, a conductive layer, a first insulation layer arranged between the first metal layer and the second metal layer, and a second insulation layer arranged between the second metal layer and the conductive layer; the first signal line portion is electrically coupled to the second signal line portion via a conductive pattern formed at the conductive layer and a through-hole passing through the second insulation layer; and the first metal layer, the second metal layer and the conductive layer are arranged sequentially in a direction away from the base substrate.

In at least one embodiment of the present disclosure, the array substrate further includes a base substrate, and an orthogonal projection of the first signal line portion onto the base substrate at least partially overlaps with an orthogonal projection of the second signal line portion onto the base substrate.

FIG. 5 is a schematic view showing the layout of six signal lines in the array substrate according to at least one embodiment of the present disclosure (the six signal lines are for illustrative purposes, and the specific quantity of signal lines will not be particularly defined herein).

In FIG. 5, L1 represents a first signal line, L2 represents a second signal line, L3 represents a third signal line, L4 represents a fourth signal line, L5 represents a fifth signal line, and L6 represents a sixth signal line.

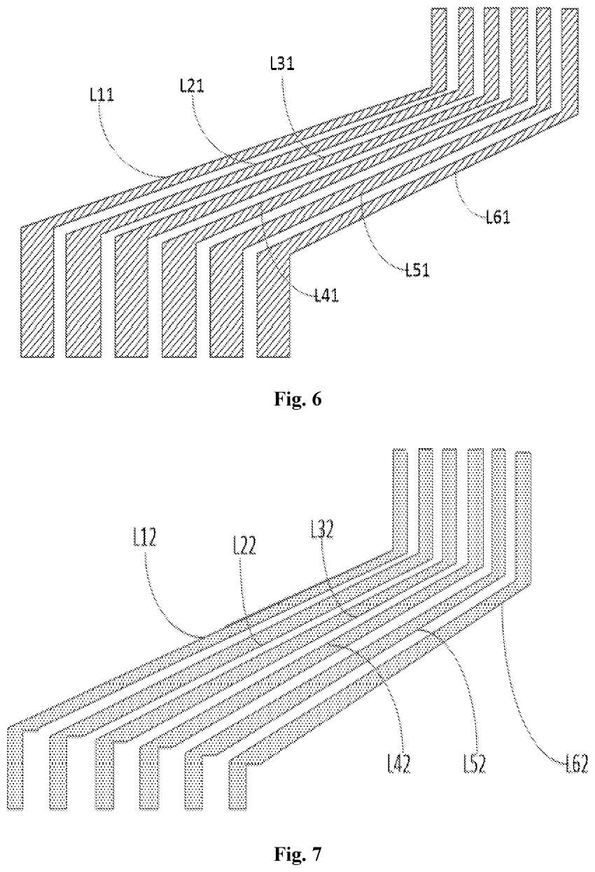

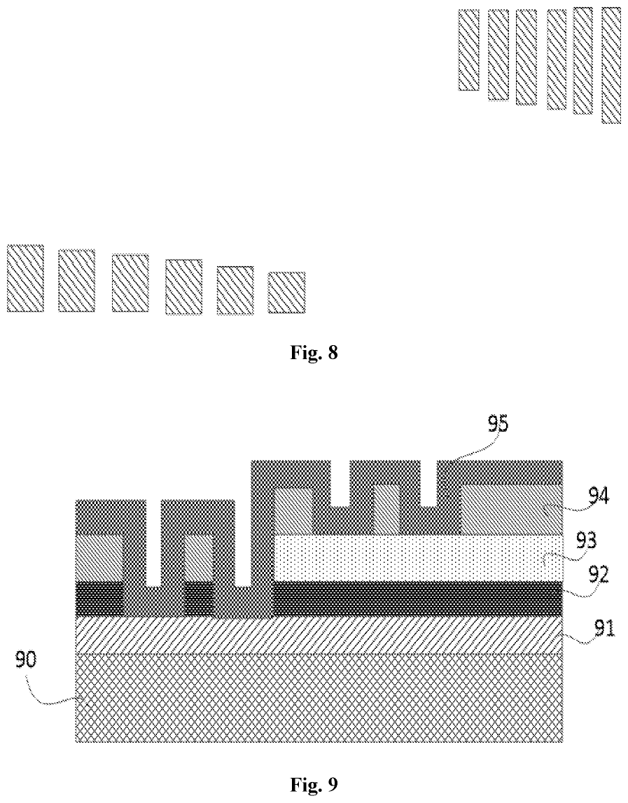

FIG. 6 is a schematic view showing the layout of the gate metal layer in FIG. 5, FIG. 7 is a schematic view showing the layout of the source/drain metal layer in FIG. 5, and FIG. 8 is a schematic view showing the layout of the conductive layer in FIG. 5.

In FIG. 6, L11 represents a first signal line portion of the first signal line, L21 represents a first signal line portion of the second signal line, L31 represents a first signal line portion of the third signal line, L41 represents a first signal line portion of the fourth signal line, L51 represents a first signal line portion of the fifth signal line, and L61 represents a first signal line portion of the sixth signal line.

In FIG. 7, L12 represents a second signal line portion of the first signal line, L22 represents a second signal line portion of the second signal line, L32 represents a second signal line portion of the third signal line, L42 represents a second signal line portion of the fourth signal line, L52 represents a second signal line portion of the fifth signal line, and L62 represents a second signal line portion of the sixth signal line.

FIG. 9 is a sectional view of the array substrate in FIG. 5 along line A-A′.

In FIGS. 9, 90 represents the base substrate, 91 represents the gate metal layer, 92 represents the first insulation layer (e.g., a gate insulation layer), 93 represents the source/drain metal layer, 94 represents the second insulation layer (e.g., a passivation layer PVX), and 95 represents the conductive layer (in a possible embodiment of the present disclosure, the conductive layer is an indium tin oxide (ITO) layer arranged at a same layer as a pixel electrode or a common electrode).

As shown in FIGS. 5 to 9, an orthogonal projection of L11 onto the base substrate at least partially overlaps with an orthogonal projection of L12 onto the base substrate, an orthogonal projection of L21 onto the base substrate at least partially overlaps with an orthogonal projection of L22 onto the base substrate, an orthogonal projection of L31 onto the base substrate at least partially overlaps with an orthogonal projection of L32 onto the base substrate, an orthogonal projection of L41 onto the base substrate at least partially overlaps with an orthogonal projection of L42 onto the base substrate, an orthogonal projection of L51 onto the base substrate at least partially overlaps with an orthogonal projection of L52 onto the base substrate, and an orthogonal projection of L61 onto the base substrate at least partially overlaps with an orthogonal projection of L62 onto the base substrate. In a possible embodiment of the present disclosure, the orthogonal projection of the first signal line portion onto the base substrate may completely overlap with the orthogonal projection of the second signal line portion onto the base substrate.

During the implementation, in a case that each signal line is a double-layered line, a resistance of the signal line may be reduced from 0.85 ohm to 0.43 ohm, the current flowing through the signal line is not affected, and a temperature of the signal line is directly reduced from 53.3 °C to 42.2 °C.

In a possible embodiment of the present disclosure, the plurality of pad terminals includes a first pad terminal for providing a clock signal and a third pad terminal for providing a data voltage; the first pad terminal includes at least one first sub-pad and at least one second sub-English pad; the third pad terminal includes at least one third sub-pad; the first sub-pad includes a first sub-pad portion formed at the first metal layer and a second sub-pad portion formed at the second metal layer; the second sub-pad includes a third sub-pad portion formed at the first metal layer; and the third sub-pad includes a fourth sub-pad portion formed at the first metal layer.

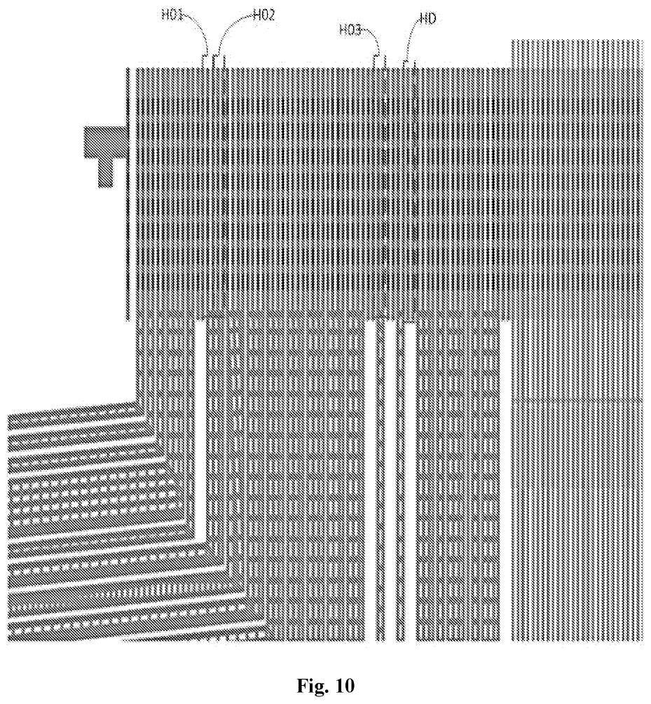

FIG. 10 is a schematic view showing an actual connection relationship between the pad terminals and the signal lines.

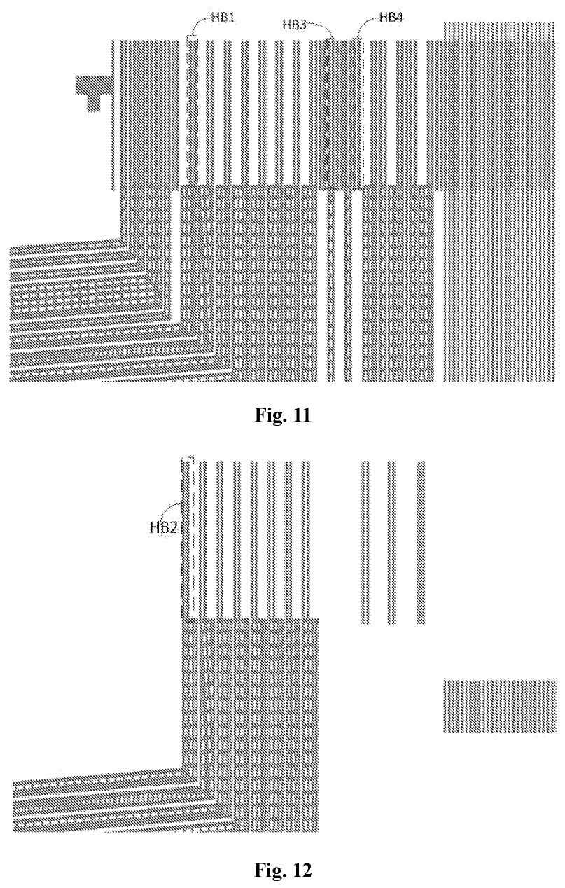

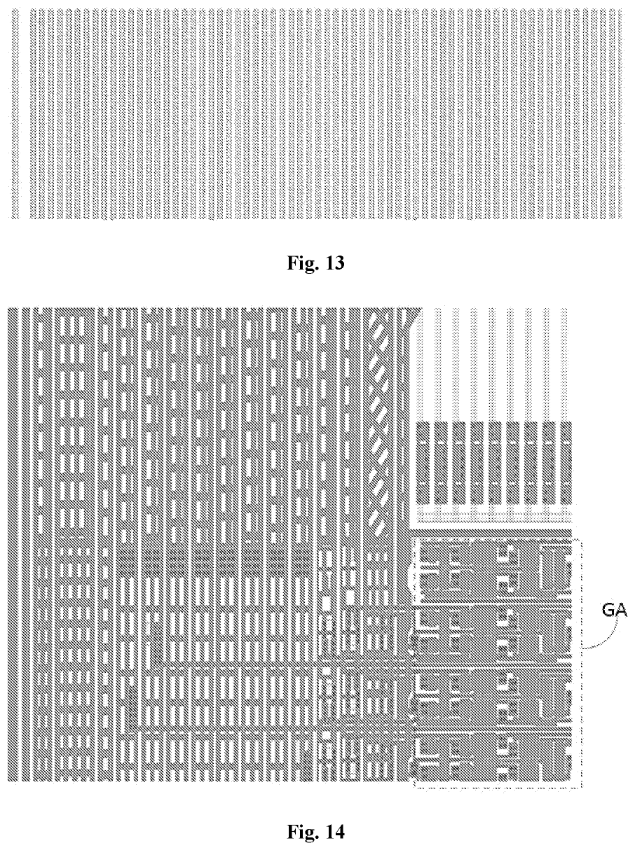

FIG. 11 is a schematic view showing the layout of the gate metal layer in FIG. 10, FIG. 12 is a schematic view showing the layout of the source/drain metal layer in FIG. 10, and FIG. 13 is a schematic view showing the layout of the conductive layer in FIG. 10.

As shown in FIG. 10, the first pad terminal for transmitting the clock signal includes a first sub-pad H01 and a second sub-pad H02. H03 represents a third sub-pad H03 for transmitting the data voltage.

As shown in FIG. 11, the first sub-pad H01 includes a first sub-pad portion HB1, the second sub-pad H02 includes a third sub-pad portion HB3, and the third sub-pad H03 includes a fourth sub-pad portion HB4.

As shown in FIG. 12, the first sub-pad H01 includes a second sub-pad portion HB2.

In FIG. 10, HD represents a dummy pad.

During the implementation, each pad terminal further includes a conductive layer (e.g., the conductive layer is made of ITO). Referring to FIGS. 11 and 12, the first sub-pad portion HB1 is arranged at the gate metal layer, and it includes two branches. The second sub-pad portion HB2 is arranged at the source/drain metal layer, and it includes two branches. The two branches of HB1 and the two branches of HB2 are arranged opposite to each other (the two branches of HB1 are arranged on the right, and the two branches of HB2 are arranged on the left, i.e., the two branches of HB1 do not overlap with the two branches of HB2 in a direction perpendicular to the base substrate). HB1 is electrically coupled to HB2 via the conductive layer and the through-hole. The conductive layer is exposed, so as to be bound to a Flexible Printed Circuit (FPC). Through a conductive pattern of the conductive layer, the sub-pad portion of a pad terminal formed at the gate metal layer is electrically coupled to the sub-pad portion of the same pad terminal formed at the source/drain metal layer.

FIG. 14 is an actual schematic view showing a connection relationship between the signal lines and the GOA module. In FIG. 14, GA represents a part of driving circuits in the driving module.

In at least one embodiment of the present disclosure, the driving module includes a plurality of levels of driving circuits; the driving circuit includes an output transistor; a gate electrode of the output transistor is electrically coupled to a first node, a first electrode of the output transistor is electrically coupled to a clock signal line, and a second electrode of the output transistor is electrically coupled to a driving signal output end; and a width-to-length ratio of a channel of the output transistor is smaller than a first width-to-length ratio threshold.

During the implementation, the driving circuit includes the output transistor, and the output transistor is configured to control the clock signal line to be electrically coupled to or electrically decoupled from the driving signal output end under the control of a potential at the first node. Int eh related art, the channel of the output transistor has a relatively large width-to-length ratio, so a load of the clock signal line is remarkably affected, and thereby the temperature of the signal line is high. Through reducing the width-to-length ratio of the channel of the output transistor, it is able to reduce the current flowing through the clock signal line, thereby to reduce the temperature of the signal line. In addition, in a case that the width-to-length ratio of the channel of the output transistor decreases, a fall time Tf of a driving signal increases, so a width-to-length ratio of a channel of an output resetting transistor may be increased to compensate for the decrease in the fall time.

In a possible embodiment of the present disclosure, the first width-to-length ratio threshold may be greater than or equal to 6000/4.3 and smaller than or equal to 20000/4.3. In a possible embodiment of the present disclosure, the first width-to-length ratio threshold is greater than or equal to 9000/4.3 and smaller than or equal to 12000/4.3, e.g., 11000/4.3, 10500/4.3, or 12000/4.3.

In at least one embodiment of the present disclosure, the driving circuit further includes an output resetting transistor; a gate electrode of the output resetting transistor is electrically coupled to a resetting end, a first electrode of the output resetting transistor is electrically coupled to the driving signal output end, and a second electrode of the output resetting transistor is electrically coupled to a first voltage end; and a width-to-length ratio of a channel of the output resetting transistor is greater than a second width-to-length ratio threshold.

In a possible embodiment of the present disclosure, the second width-to-length ratio threshold may be greater than or equal to 10000/4.3 and smaller than or equal to 25000/4.3. In a possible embodiment of the present disclosure, the second width-to-length ratio threshold is greater than or equal to 13000/4.3 and smaller than or equal to 19000/4.3, e.g., 14000/4.3, 15000/4.3, or 16000/4.3.

In a possible embodiment of the present disclosure, the width-to-length ratio of the channel of the output transistor of the driving circuit may be smaller than the width-to-length ratio of the channel of the output resetting channel of the driving circuit. For example, a ratio of the width-to-length ratio of the channel of the output transistor to the width-to-length ratio of the channel of the output resetting transistor is within a range of 1.1 to 1.4, with endpoints being included. In this way, it is able to reduce the temperature of the peripheral signal line and prevent the normal operation of the driving circuit from being adversely affected.

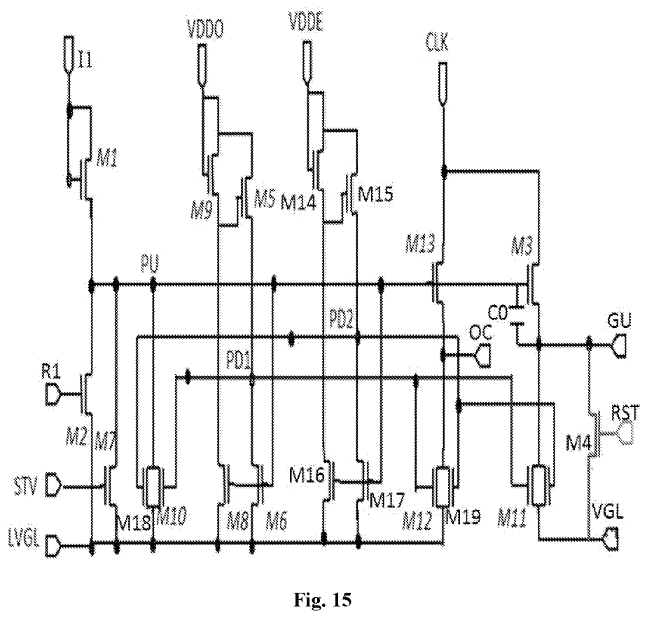

As shown in FIG. 15, in at least one embodiment of the present disclosure, the driving circuit includes a first transistor M1, a second transistor M2, an output transistor M3, an output resetting transistor M4, a fifth transistor M5, a sixth transistor M6, a seventh transistor M7, an eighth transistor M8, a ninth transistor M9, a tenth transistor M10, an eleventh transistor M11, a twelfth transistor M12, a thirteenth transistor M13, a fourteenth transistor M14, a fifteenth transistor M15, a sixteenth transistor M16, a seventeenth transistor M17, an eighteenth transistor M18, a nineteenth transistor M19, and a storage capacitor C0.

In FIG. 15, I1 represents an input end, R1 represents a resetting signal end, STV0 represents a frame resetting end, LVGL represents a first low voltage end, VGL represents a second low voltage end, PU represents a first node, PD1 represents a first one of second nodes, PD2 represents a second one of second nodes, OC represents a carry out end, GU represents a driving signal output end, RST represents a resetting end, CLK represents a clock signal end, VDDO represents a first control voltage end, and VDDE represents a second control voltage end.

FIG. 15 merely shows an example of the driving circuit, and it shall not be construed as limiting the structure of the driving circuit.

For example, in a case that a channel of a driving transistor in the driving circuit has a length of 4.3 μm, in the related art, a width-to-length ratio of a channel of M3 may be 17500/4.3, and a width-to-length ratio of a channel of M4 may be 16000/4.3. In the presence of a bezel, a width of the channel of M3 may be adjusted in simulation with a step value of 1000 μm. In a case that the width-to-length ratio of the channel of M3 is reduced to 10500/4.3, a root-mean-square (RMS) value of the current flowing through the corresponding clock signal line is decreased from 35.33 mA to 30.16 mA, a fall time of the driving signal is increased from 1.88 μs to 2.06 μs, and the temperature of the clock signal line is obviously decreased from 53.3 °C to 47.7 °C. The fall time of the driving signal is less affected, and a loss of the image quality is relatively small.

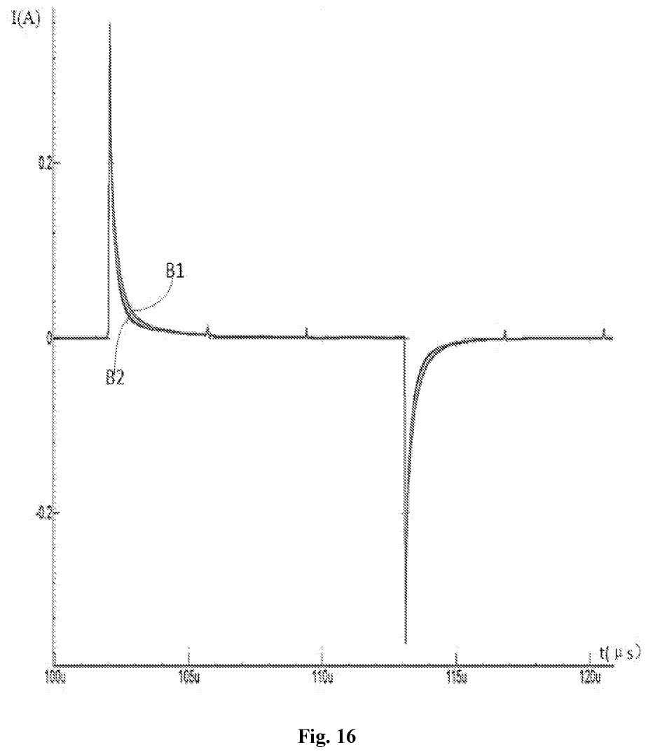

In FIG. 16, B1 is an oscillogram of a current I on the clock signal line before the width-to-length ratio of the channel of M3 decreases, and B2 is an oscillogram of the current I on the clock signal line after the width-to-length ratio of the channel of M3 decreases.

In FIG. 16, an x-axis represents the current I on the clock signal line, in unit of A, and a y-axis represents time t, in unit of us.

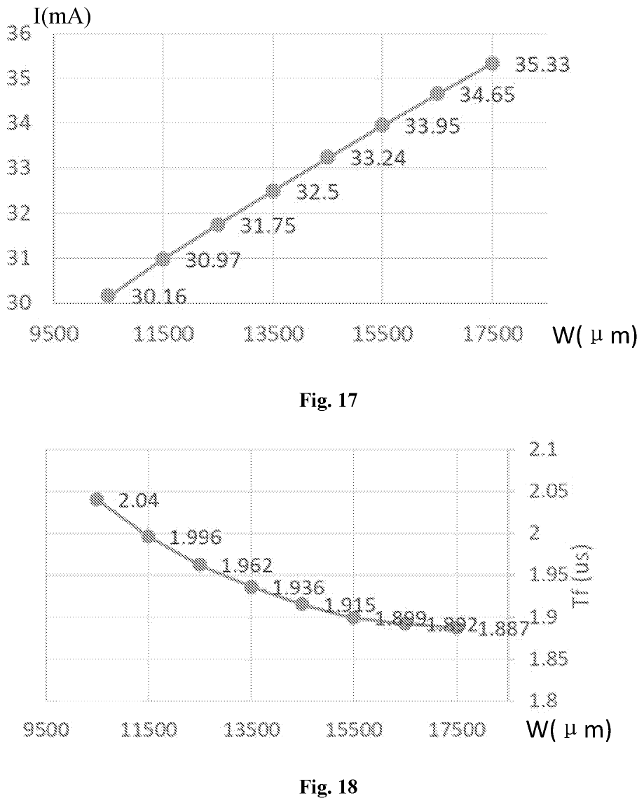

FIG. 17 is a comparative diagram of the width W of the channel of M3 and the current I on the clock signal line, and FIG. 18 is a comparative diagram of the width of the channel of M3 and the fall time Tf of the driving signal.

In at least one embodiment of the present disclosure, the signal line is configured to transmit a clock signal; and a rising edge of the clock signal includes at least two steps. To be specific, a CLK charge sharing circuit is added at a circuit driving end so that the rising edge of the clock signal line includes at least two steps.

During the implementation, the rising edge of the clock signal includes a plurality steps, i.e., an intermediate voltage GPM is added in a case that a potential of the clock signal jumps from a low voltage Vgl to a high voltage Vgh, and a large, single peak of the current at the rising edge of the clock signal is split into two smaller peaks, so as to reduce the current on the clock signal line.

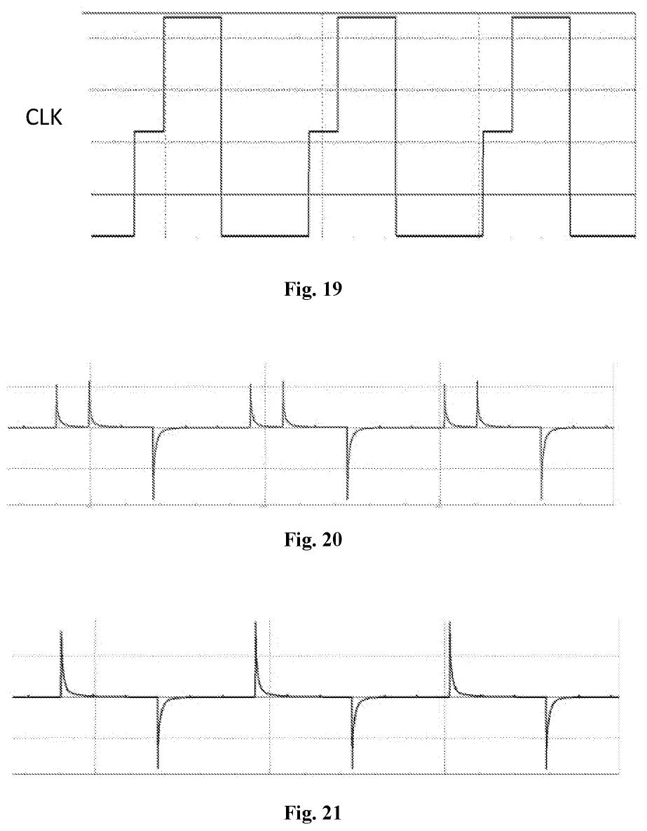

In at least one embodiment of the present disclosure, FIG. 19 is an oscillogram of the clock signal CLK.

In FIG. 19, a voltage value of the intermediate voltage GPM is (Vgl+Vgh)/2, a duration of the clock signal CLK whose potential is GPM is 0.5 H, and 1 H represents a scanning time for one row. Through simulation, an RMS value of the current on the clock signal line is decreased from 35.33 mA to 30.82 mA.

FIG. 20 is an oscillogram of the current I on the clock signal line in a case that the rising edge of the clock signal includes two steps, and FIG. 21 is an oscillogram of the current I on the clock signal line in a case that the rising edge of the clock signal includes only one step in the related art.

The present disclosure further provides in some embodiments a display device including a circuit board and the above-mentioned array substrate. The circuit board is electrically coupled to a binding sub-region of the array substrate, and configured to provide a driving control signal for a driving module of the array substrate via the binding sub-region. The quantity of circuit boards corresponds to the quantity of binding sub-regions of the array substrate. For example, in a case that there are two binding sub-regions, two circuit boards may be provided.

In at least one embodiment of the present disclosure, the display device includes at least one circuit board, the circuit board includes a binding region, and at least one binding region of the at least one circuit board includes at least three signal providing regions. The binding region includes a plurality of connecting finger structures, so as to be electrically coupled to the pad terminals of the array substrate (via welding or an Anisotropic Conductive Film (ACF)), thereby to transmit a data signal provided by the data line in the display region and a control signal provided by the driving circuit.

The circuit board may be a flexible circuit board, and the circuit board further includes a data driving chip.

In at least one embodiment of the present disclosure, the display device includes two circuit boards, each circuit board is bound to a corresponding binding sub-region, and the circuit board includes a plurality of first connecting fingers, a plurality of second connecting fingers and a plurality of third connecting fingers. The first connecting finger and the second connecting finger are arranged at two opposite sides of the circuit board, and the third connecting finger is arranged between the first connecting finger and the second connecting finger. The first connecting finger is electrically coupled to a first pad terminal, and configured to transmit a driving control signal. The second connecting finger is electrically coupled to a second pad terminal, and configured to transmit the driving control signal. The third connecting finger is electrically coupled to a third pad terminal, and configured to transmit a data voltage.

In at least one embodiment of the present disclosure, the display device includes at least three circuit boards, each circuit board is bound to a corresponding binding sub-region, and the circuit board includes a plurality of first connecting fingers. The first connecting finger is electrically coupled to the first pad terminal, and configured to transmit the driving control signal. The first connecting finger of a leftmost circuit board is arranged at a left end of the circuit board, the first connecting finger of a rightmost circuit board is arranged at a right end of the circuit board, and the first connecting finger of a middle circuit board is arranged at a left end or a right end of the circuit board.

In at least one embodiment of the present disclosure, the display device includes one circuit board, and the circuit board is bound to a corresponding binding sub-region and includes a plurality of first connecting fingers. The first connecting finger is electrically coupled to the first pad terminal, and configured to transmit the driving control signal. The first connecting finger is arranged at a left end, a right end, or a middle portion of the circuit board.

The above are merely the preferred embodiments of the present disclosure. It should be appreciated that, a person skilled in the art may further make improvements and modifications without departing from the principle of the present disclosure, and these improvements and modifications shall also fall within the scope of the present disclosure.

1. An array substrate, comprising a display region and a non-display region, the non-display region comprising at least one binding sub-region, the binding sub-region being electrically coupled to a circuit board,
wherein the array substrate further comprises a driving module arranged in the non-display region, and the circuit board provides a driving control signal for the driving module via the binding sub-region;
the at least one binding sub-region comprises at least three signal providing regions; and
the at least one binding sub-region comprises a plurality of pad terminals arranged in the at least three signal providing regions, and the pad terminal provides the driving control signal for the driving module via a signal line.

2. The array substrate according to claim 1, wherein the non-display region comprises a plurality of binding sub-regions; the plurality of pad terminals is arranged in a first direction;
the binding sub-region comprises a first signal providing region and a second signal providing region;
the plurality of pad terminals comprises a plurality of first pad terminals and a plurality of second pad terminals;
the first pad terminal corresponds to the first signal providing region, and the second pad terminal corresponds to the second signal providing region; and
the first pad terminal and the second pad terminal are arranged at two opposite sides of the binding sub-region.

3. The array substrate according to claim 2, further comprising a data line, wherein at least a portion of the data line is arranged in the display region;
the plurality of pad terminals further comprises a plurality of third pad terminals;
the third pad terminal is arranged between the first pad terminal and the second pad terminal; and
the third pad terminal is electrically coupled to the data line and configured to apply a data voltage to the data line.

4. The array substrate according to claim 1, wherein the driving control signal comprises at least one of a clock signal, a common electrode voltage signal, a direct-current voltage signal, or a frame start signal.

5. The array substrate according to claim 2, wherein the signal line is configured to provide a clock signal for the driving module;
the non-display region comprises a first binding sub-region and a second binding sub-region;
the array substrate further comprises at least one clock signal line arranged between the driving module and the binding sub-region and extending in the first direction;
the clock signal line comprises a first end and a second end arranged opposite to each other;
a first signal providing region of the first binding sub-region is arranged at a first end of the first binding sub-region, and a second signal providing region of the first binding sub-region is arranged at a second end of the first binding sub-region;
a first signal providing region of the second binding sub-region is arranged at a first end of the second binding sub-region, and a second signal providing region of the second binding sub-region is arranged at a second end of the second binding sub-region; and
the first end of the first binding sub-region is close to the first end of the clock signal line, and the second end of the second binding sub-region is close to the second end of the clock signal line.

6. The array substrate according to claim 5, wherein the clock signal line is arranged at a first metal layer;
the first binding sub-region is electrically coupled to the clock signal line via a signal line arranged in the second signal providing region of the first binding sub-region and formed at a second metal layer;
the second binding sub-region is electrically coupled to the clock signal line via a signal line arranged in the first signal providing region of the second binding sub-region and formed at the second metal layer; and
the first metal layer and the second metal layer are different metal layers.

7. The array substrate according to claim 6, wherein the first binding sub-region is electrically coupled to the clock signal line via a signal line arranged in the first signal providing region of the first binding sub-region and formed at the first metal layer; and
the second binding sub-region is electrically coupled to the clock signal line via a signal line arranged in the second signal providing region of the second binding sub-region and formed at the first metal layer.

8. The array substrate according to claim 1, wherein the non-display region comprises M binding sub-regions arranged in a first direction, where M is an integer greater than or equal to 3;
the plurality of pad terminals is arranged in the first direction; and
the signal providing region of the binding sub-region is arranged at a first end or a second end of the binding sub-region.

9. The array substrate according to claim 8, wherein the signal line is configured to provide a clock signal for the driving module;
the array substrate further comprises at least one clock signal line arranged between the driving module and the binding sub-region and extending in the first direction;
the clock signal line comprises a first end and a second end;
a signal providing region of a first binding sub-region is arranged at a first end of the first binding sub-region, and a signal providing region of an M^{th} binding sub-region is arranged at a second end of the M^{th} binding sub-region;
a signal providing region of an m^{th} binding sub-region is arranged at a first end or a second end of the m^{th} binding sub-region, where m is an integer greater than 1 and smaller than M; and
the first end of the first binding sub-region is close to the first end of the clock signal line, and the second end of the M^{th} binding sub-region is close to the second end of the clock signal line.

10. The array substrate according to claim 1, wherein the non-display region comprises one binding sub-region;
the plurality of pad terminals is arranged in a first direction;
the binding sub-region comprises N signal providing regions, where N is an integer greater than or equal to 3; and
two signal providing regions of the N signal providing regions are arranged at two opposite sides of the binding sub-region, and the remaining signal providing regions of the N signal providing regions other than the two signal providing regions are arranged in the middle of the binding sub-region.

11. The array substrate according to claim 10, wherein the signal line is configured to provide a clock signal for the driving module;
the array substrate further comprises at least one clock signal line arranged between the driving module and the binding sub-region and extending in the first direction; the clock signal line comprises a first end and a second end; and
a first signal providing region of the binding sub-region is arranged at a first end of the binding sub-region, an Nₜₕ signal providing region of the binding sub-region is arranged at a second end of the binding sub-region, and an n^{th} signal providing region of the binding sub-region is arranged in the middle of the binding sub-region, where n is an integer greater than 1 and smaller than N.

12. The array substrate according to claim 5, wherein the non-display region comprises a first non-display region arranged at a first side of the display region; and
the clock signal line, the driving module and the binding sub-region are arranged in the first non-display region.

13. The array substrate according to claim 1, wherein the signal line comprises at least two signal line portions electrically coupled to each other; and
the at least two signal line portions are formed at different metal layers.

14. The array substrate according to claim 13, further comprising a first metal layer and a second metal layer, wherein the signal line comprises a first signal line portion and a second signal lien portion; and
the first signal line portion is formed at the first metal layer, and the second signal line portion is formed at the second metal layer.

15. The array substrate according to claim 14, further comprising a base substrate, a conductive layer, a first insulation layer arranged between the first metal layer and the second metal layer, and a second insulation layer arranged between the second metal layer and the conductive layer, wherein the first signal line portion is electrically coupled to the second signal line portion via a conductive pattern formed at the conductive layer and a through-hole passing through the second insulation layer; and
the first metal layer, the second metal layer and the conductive layer are arranged sequentially in a direction away from the base substrate.

16. The array substrate according to claim 14, further comprising a base substrate, wherein an orthogonal projection of the first signal line portion onto the base substrate at least partially overlaps with an orthogonal projection of the second signal line portion onto the base substrate.

17. The array substrate according to claim 14, wherein the plurality of pad terminals comprises a first pad terminal for providing a clock signal and a third pad terminal for providing a data voltage;
the first pad terminal comprises at least one first sub-pad and at least one second sub-pad;
the third pad terminal comprises at least one third sub-pad;
the first sub-pad comprises a first sub-pad portion formed at the first metal layer and a second sub-pad portion formed at the second metal layer;
the second sub-pad comprises a third sub-pad portion formed at the first metal layer; and
the third sub-pad comprises a fourth sub-pad portion formed at the first metal layer.

18. The array substrate according to claim 1, wherein the driving module comprises a plurality of levels of driving circuits;
the driving circuit comprises an output transistor;
a gate electrode of the output transistor is electrically coupled to a first node, a first electrode of the output transistor is electrically coupled to a clock signal line, and a second electrode of the output transistor is electrically coupled to a driving signal output end; and
a width-to-length ratio of a channel of the output transistor is smaller than a first width-to-length ratio threshold;
wherein the driving circuit further comprises an output resetting transistor;
a gate electrode of the output resetting transistor is electrically coupled to a resetting end, a first electrode of the output resetting transistor is electrically coupled to the driving signal output end, and a second electrode of the output resetting transistor is electrically coupled to a first voltage end; and
a width-to-length ratio of a channel of the output resetting transistor is greater than a second width-to-length ratio threshold.

19. (canceled)

20. The array substrate according to claim 1, wherein the signal line is configured to transmit a clock signal; and
a rising edge of the clock signal comprises at least two steps.

21. A display device, comprising a circuit board and the array substrate according to claim 1, wherein the circuit board is electrically coupled to a binding sub-region of the array substrate, and configured to provide a driving control signal for a driving module of the array substrate via the binding sub-region.
